(19) United States
(12) Patent Application Publication
(10) Pub. No.: US 2014/0184027 A1
(43) Pub. Date: Jul. 3, 2014

(54) Layout and Method of Singulating Miniature Ultrasonic Transducers

(71) Applicant: VOLCANO CORPORATION, San Diego, CA (US)

(72) Inventors: Cheryl Rice, San Diego, CA (US); Dongjuan Chris Xi, San Marcus, CA (US)

(73) Assignee: VOLCANO CORPORATION, San Diego, CA (US)

(21) Appl. No.: 14/106,899

(22) Filed: Dec. 16, 2013

Related U.S. Application Data
(60) Provisional application No. 61/747,506, filed on Dec. 31, 2012.

(51) Int. Cl. H01L 41/04; H01L 41/332; H01L 41/16

(52) U.S. Cl. CPC H01L 41/04; H01L 41/16; H01L 41/332
USPC 310/348; 216/17

(57) ABSTRACT

The present disclosure provides a method of singulating a plurality of miniature ultrasound transducers from a wafer. The method includes receiving a wafer on which a plurality of miniature ultrasound transducers is formed. The miniature ultrasound transducers each include a transducer membrane containing a piezoelectric material. The method includes etching, from a front side of the wafer, a plurality of trenches into the wafer. Each trench at least partially encircles a respective one of the miniature ultrasound transducers in a top view. Each trench includes an approximately rounded segment. The method includes thinning the wafer from a back side opposite the front side. The thinning the wafer is performed such that the trenches are open to the back side. The method includes performing a dicing process to the wafer to separate the miniature ultrasound transducers from one another. The dicing process is performed without making crossing cuts in the wafer.

### PRIORITY DATA

This application claims priority to Provisional Patent Application No. 61/747,506, filed Dec. 31, 2012, and entitled “Layout and Method of Singulating Miniature Ultrasonic Transducers,” the disclosure of which is hereby incorporated by reference in its entirety.

### TECHNICAL FIELD

The present disclosure relates generally to intravascular ultrasound (IVUS) imaging, and in particular, to singulating a plurality of IVUS ultrasound transducers from a wafer.

### BACKGROUND

Intravascular ultrasound (IVUS) imaging is widely used in interventional cardiology as a diagnostic tool for assessing a vessel, such as an artery, within the human body to determine the need for treatment, to guide intervention, and/or to assess its effectiveness. An IVUS imaging system uses ultrasound echoes to form a cross-sectional image of the vessel of interest. Typically, IVUS imaging uses a transducer on an IVUS catheter that both emits ultrasound signals (waves) and receives the reflected ultrasound signals. The emitted ultrasound signals (often referred to as ultrasound pulses) pass easily through most tissues and blood, but they are partially reflected as the result of impedance variation arising from tissue structures (such as the various layers of the vessel wall), red blood cells, and other features of interest. The IVUS imaging system, which is connected to the IVUS catheter by way of a patient interface module, processes the received ultrasound signals (often referred to as ultrasound echoes) to produce a cross-sectional image of the vessel where the IVUS catheter is located.

IVUS catheters typically employ one or more transducers to transmit ultrasound signals and receive reflected ultrasound signals. These transducers are formed on a wafer. The wafer needs to be singulated to form individual dies that each contain a transducer. However, conventional layouts and methods of singulating the transducer wafer may have limitations. For example, typically the cuts can be made either in a vertical direction or in a horizontal direction. As such, the resulting dies may assume a square or rectangular shape, which may not be desired in certain transducer applications.

Therefore, while conventional wafer layouts and methods of singulating a transducer wafer transducers are generally adequate for their intended purposes, they have not been entirely satisfactory in every aspect.

### SUMMARY

Ultrasounds transducers are used in Intravascular ultrasound (IVUS) imaging to help assess medical conditions inside a human body. As a part of its operation, an ultrasound transducer has electrodes that are used to apply electrical signals to the transducer. To extract individual dies (that each contain a transducer) from a wafer, the wafer needs to be diced. According to the present disclosure, each ultrasound transducer is formed on a substrate that has a round or curved profile in a top view. The rounded profile allows the die containing the ultrasound transducer to be more flexibly implemented in transducer applications that may be incompatible with a square or rectangular shaped die.

The present disclosure provides various embodiments of an ultrasound transducer for use in intravascular ultrasound (IVUS) imaging. An exemplary ultrasound transducer includes a substrate. The ultrasound transducer also includes a well formed the substrate. The ultrasound transducer also includes a transducer membrane disposed over the well. The transducer membrane contains a piezoelectric layer. At least a portion of the substrate has an approximately rounded profile in a top view.

The present disclosure further provides a wafer. The wafer includes a substrate and a plurality of miniature ultrasonic transducers formed on the substrate. Each miniature ultrasonic transducer includes a transducer membrane that contains a piezoelectric material. Each miniature ultrasonic transducer is at least partially surrounded in a top view by a trench formed in the substrate. At least a portion of the trench has an approximately curved profile in a top view.

The present disclosure further provides a method of singulating a plurality of miniature ultrasound transducers from a wafer. The method includes: receiving a wafer on which a plurality of miniature ultrasound transducers are formed, the miniature ultrasound transducers each including a transducer membrane that contains a piezoelectric material; etching, from a front side of the wafer, a plurality of trenches into the wafer, wherein each trench at least partially encircles a respective one of the miniature ultrasound transducers in a top view, and wherein each trench includes an approximately rounded segment; thinning the wafer from a back side opposite the front side, wherein the thinning the wafer is performed such that the trenches are open to the back side; and performing a dicing process to the wafer to separate the miniature ultrasound transducers from one another, wherein the dicing process is performed without making crossing cuts in the wafer.

Both the foregoing general description and the following detailed description are exemplary and explanatory in nature and are intended to provide an understanding of the present disclosure without limiting the scope of the present disclosure. In that regard, additional aspects, features, and advantages of the present disclosure will become apparent to one skilled in the art from the following detailed description.

### BRIEF DESCRIPTIONS OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. In addition, the present disclosure may repeat reference numerals and/or letters in the various examples. This repetition is for the purpose of simplicity and clarity and does not in itself dictate a relationship between the various embodiments and/or configurations discussed.

FIG. 1 is a schematic illustration of an intravascular ultrasound (IVUS) imaging system according to various aspects of the present disclosure.

FIGS. 2-7 are diagrammatic cross-sectional side views of an ultrasound transducer at different stages of fabrication according to various aspects of the present disclosure.

FIGS. 8-9 are diagrammatic top views of a portion of a wafer containing the transducers of FIGS. 2-7 according to various aspects of the present disclosure.

FIG. 10 is a diagrammatic cross-sectional side view of a transducer assembly having an angled transducer according to various aspects of the present disclosure.

FIG. 11 is a flowchart of a method of performing a singulation process according to various aspects of the present disclosure.

FIGS. 12-17 are diagrammatic top views of a portion of a wafer containing the transducers according to various aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. For example, the present disclosure provides an ultrasound imaging system described in terms of cardiovascular imaging, however, it is understood that such description is not intended to be limited to this application. In some embodiments, the ultrasound imaging system includes an intravascular imaging system. The imaging system is equally well suited to any application requiring imaging within a small cavity. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

There are primarily two types of catheters in common use today: solid-state and rotational. An exemplary solid-state catheter uses an array of transducers (typically 64) distributed around a circumference of the catheter and connected to an electronic multiplexer circuit. The multiplexer circuit selects transducers from the array for transmitting ultrasound signals and receiving reflected ultrasound signals. By stepping through a sequence of transmit-receive transducer pairs, the solid-state catheter can synthesize the effect of a mechanically scanned transducer element, but without moving parts. Since there is no rotating mechanical element, the transducer array can be placed in direct contact with blood and vessel tissue with minimal risk of vessel trauma, and the solid-state scanner can be wired directly to the imaging system with a simple electrical cable and a standard detachable electrical connector.

An exemplary rotational catheter includes a single transducer located at a tip of a flexible driveshaft that spins inside a sheath inserted into the vessel of interest. The transducer is typically oriented such that the ultrasound signals propagate generally perpendicular to an axis of the catheter. In the typical rotational catheter, a fluid-filled (e.g., saline-filled) sheath protects the vessel tissue from the spinning transducer and driveshaft while permitting ultrasound signals to freely propagate from the transducer into the tissue and back. As the driveshaft rotates (for example, at 30 revolutions per second), the transducer is periodically excited with a high voltage pulse to emit a short burst of ultrasound. The ultrasound signals are emitted from the transducer, through the fluid-filled sheath and sheath wall, in a direction generally perpendicular to an axis of rotation of the driveshaft. The same transducer then listens for returning ultrasound signals reflected from various tissue structures, and the imaging system assembles a two dimensional image of the vessel cross-section from a sequence of several hundred of these ultrasound pulse/echo acquisition sequences occurring during a single revolution of the transducer.

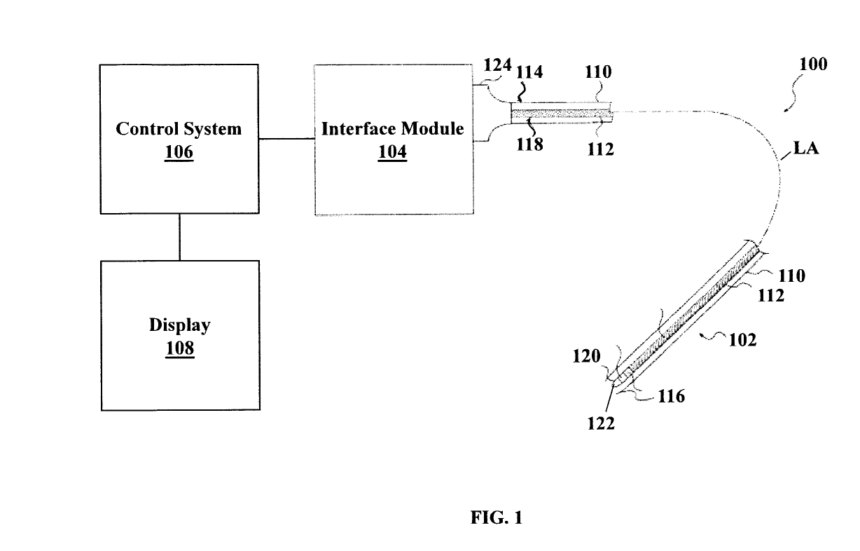

FIG. 1 is a schematic illustration of an ultrasound imaging system 100 according to various aspects of the present disclosure. In some embodiments, the ultrasound imaging system 100 includes an intravascular ultrasound imaging system (IVUS). The IVUS imaging system 100 includes an IVUS catheter 102 coupled by a patient interface module (PIM) 104 to an IVUS control system 106. The control system 106 is coupled to a monitor 108 that displays an IVUS image (such as an image generated by the IVUS system 100).

In some embodiments, the IVUS catheter 102 is a rotational IVUS catheter, which may be similar to a Revolution® Rotational IVUS Imaging Catheter available from Volcano Corporation and/or rotational IVUS catheters disclosed in U.S. Pat. No. 5,243,988 and U.S. Pat. No. 5,546,948, both of which are incorporated herein by reference in their entirety. The catheter 102 includes an elongated, flexible catheter sheath 110 (having a proximal end portion 114 and a distal end portion 116) shaped and configured for insertion into a lumen of a blood vessel (not shown). A longitudinal axis LA of the catheter 102 extends between the proximal end portion 114 and the distal end portion 116. The catheter 102 is flexible such that it can adapt to the curvature of the blood vessel during use. In that regard, the curved configuration illustrated in FIG. 1 is for exemplary purposes and in no way limits the manner in which the catheter 102 may curve in other embodiments. Generally, the catheter 102 may be configured to take on any desired straight or arcuate profile when in use.

A rotating imaging core 112 extends within the sheath 110. The imaging core 112 has a proximal end portion 118 disposed within the proximal end portion 114 of the sheath 110 and a distal end portion 120 disposed within the distal end portion 116 of the sheath 110. The distal end portion 116 of the sheath 110 and the distal end portion 120 of the imaging core 112 are inserted into the vessel of interest during operation of the IVUS imaging system 100. The usable length of the catheter 102 (for example, the portion that can be inserted into a patient, specifically the vessel of interest) can be any suitable length and can be varied depending upon the application. The proximal end portion 114 of the sheath 110 and the proximal end portion 118 of the imaging core 112 are connected to the interface module 104. The proximal end portions 114, 118 are fitted with a catheter hub 124 that is removably connected to the interface module 104. The catheter hub 124 facilitates and supports a rotational interface that provides electrical and mechanical coupling between the catheter 102 and the interface module 104.

The distal end portion 120 of the imaging core 112 includes a transducer assembly 122. The transducer assembly 122 is configured to be rotated (either by use of a motor or other rotary device) to obtain images of the vessel. The transducer assembly 122 can be of any suitable type for visualizing a vessel and, in particular, a stenosis in a vessel. In the depicted embodiment, the transducer assembly 122 includes a piezoelectric micromachined ultrasonic transducer (“PMUT”) transducer and associated circuitry, such as an application-specific integrated circuit (ASIC). An exemplary PMUT used in IVUS catheters may include a polymer piezoelectric membrane, such as that disclosed in U.S. Pat. No. 6,641,540, hereby incorporated by reference in its entirety. The PMUT transducer can provide greater than 100% bandwidth for optimum resolution in a radial direction, and a spherically-focused aperture for optimum azimuthal and elevation resolution.

The transducer assembly 122 may also include a housing having the PMUT transducer and associated circuitry disposed therein, where the housing has an opening that ultrasound signals generated by the PMUT transducer travel through. Alternatively, the transducer assembly 122 includes a capacitive micromachined ultrasonic transducer (“CMUT”). In yet another alternative embodiment, the transducer assembly 122 includes an ultrasound transducer array (for example, arrays having 16, 32, 64, or 128 elements are utilized in some embodiments).

The rotation of the imaging core 112 within the sheath 110 is controlled by the interface module 104, which provides user interface controls that can be manipulated by a user. The interface module 104 can receive, analyze, and/or display information received through the imaging core 112. It will be appreciated that any suitable functionality, controls, information processing and analysis, and display can be incorporated into the interface module 104. In an example, the interface module 104 receives data corresponding to ultrasound signals (echoes) detected by the imaging core 112 and forwards the received echo data to the control system 106. In an example, the interface module 104 performs preliminary processing of the echo data prior to transmitting the echo data to the control system 106. The interface module 104 may perform amplification, filtering, and/or aggregating of the echo data. The interface module 104 can also supply high- and low-voltage DC power to support operation of the catheter 102 including the circuitry within the transducer assembly 122.

In some embodiments, wires associated with the IVUS imaging system 100 extend from the control system 106 to the interface module 104 such that signals from the control system 106 can be communicated to the interface module 104 and/or vice versa. In some embodiments, the control system 106 communicates wirelessly with the interface module 104. Similarly, it is understood that, in some embodiments, wires associated with the IVUS imaging system 100 extend from the control system 106 to the monitor 108 such that signals from the control system 106 can be communicated to the monitor 108 and/or vice versa. In some embodiments, the control system 106 communicates wirelessly with the monitor 108.

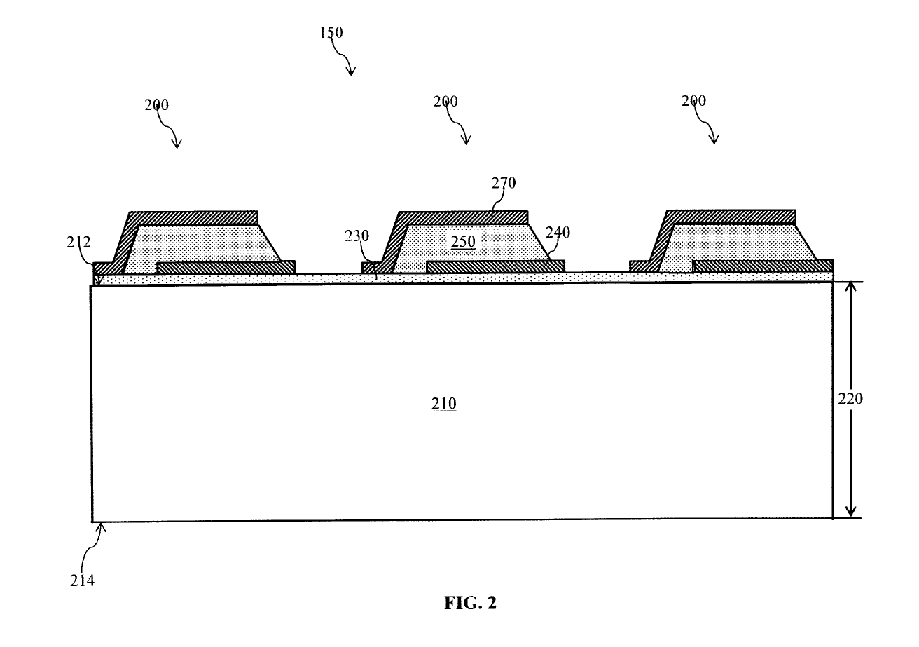

FIGS. 2-7 are diagrammatic fragmentary cross-sectional side views of a portion of a wafer 150 on which a plurality of ultrasound transducers 200 is fabricated. The FIGS. 2-7 correspond to different stages of fabrication in accordance with various aspects of the present disclosure. FIGS. 2-7 have been simplified for the sake of clarity to better understand the inventive concepts of the present disclosure. Also, since the same fabrication processes are performed to all of the ultrasonic transducers 200, the discussions below will focus on one transducer 200 for purposes of simplicity and clarity.

The ultrasound transducers 200 can each be included in the IVUS imaging system 100 of FIG. 1, for example in the transducer assembly 122. The ultrasonic transducer 200 has a small size and achieves a high resolution, so that it is well suited for intravascular imaging. In some embodiments, the ultrasonic transducer 200 has a size on the order of tens or hundreds of microns, can operate in a frequency range between about 1 mega-Hertz (MHz) to about 135 MHz, and can provide sub 50 micron resolution while providing depth penetration of at least 10 millimeters (mm). Furthermore, the ultrasonic transducer 200 is also shaped in a manner to allow a developer to define a target focus area based on a deflection depth of a transducer aperture, thereby generating an image that is useful for defining vessel morphology, beyond the surface characteristics. The various aspects of the ultrasound transducer 200 and its fabrication are discussed in greater detail below.

In the depicted embodiment, the ultrasound transducer 200 is a piezoelectric micromachined ultrasound transducer (PMUT). In other embodiments, the transducer 200 may include an alternative type of transducer. Additional features can be added in the ultrasound transducer 200, and some of the features described below can be replaced or eliminated for additional embodiments of the ultrasound transducer 200.

As is shown in FIG. 2, the transducer 200 includes a substrate 210. The substrate 210 has a surface 212 and a surface 214 that is opposite the surface 212. The surface 212 may also be referred to as a front surface or a front side, and the surface 214 may also be referred to as a back surface or a back side. In the depicted embodiment, the substrate 210 is a silicon microelectromechanical system (MEMS) substrate. The substrate 210 includes another suitable material depending on design requirements of the PMUT transducer 200 in alternative embodiments. In the illustrated embodiments, the substrate 210 is a “lightly-doped silicon substrate.” In other words, the substrate 210 comes from a silicon wafer that is lightly doped with a dopant and as a result has a resistivity in a range from about 1 ohms/cm to about 1000 ohms/cm. One benefit of the “lightly-doped silicon substrate” 210 is that it is relatively inexpensive, for example in comparison with pure silicon or undoped silicon substrates. Of course, it is understood that in alternative embodiments where cost is not as important of a concern, pure silicon or undoped silicon substrates may also be used.

The substrate 210 may also include various layers that are not separately depicted and that can combine to form electronic circuitry, which may include various microelectronic elements. These microelectronic elements may include: transistors (for example, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs)); resistors; diodes; capacitors; inductors; fuses; and/or other suitable elements. The various layers may include high-k dielectric layers, gate layers, hard mask layers, interfacial layers, capping layers, diffusion/barrier layers, dielectric layers, conductive layers, other suitable layers, or combinations thereof. The microelectronic elements could be interconnected to one another to form a portion of an integrated circuit, such as a logic device, memory device (for example, a static random access memory (SRAM)), radio frequency (RF) device, input/output (I/O) device, system-on-chip (SoC) device, other suitable types of devices, or combinations thereof.

An initial thickness 220 of the substrate 210 is measured between the surface 212 and the surface 214. In some embodiments, the initial thickness 220 is in a range from about 200 microns (um) to about 1000 um.

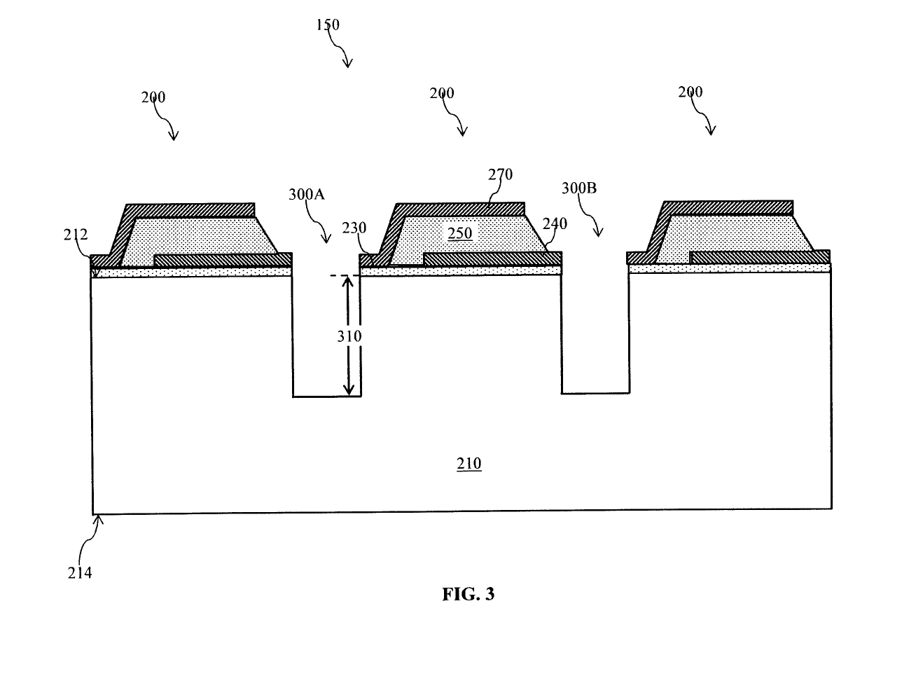

Referring now to FIG. 3, a dielectric layer 230 is formed over the surface 212 of the substrate 210. The dielectric layer 230 may be formed by a suitable deposition process known in the art, such as thermal oxidation, low temperature oxidation, chemical vapor deposition (CVD), physical vapor deposition (PVD), atomic layer deposition (ALD), or combinations thereof. The dielectric layer 230 may contain an oxide material or a nitride material, for example silicon oxide, phosphosilicate glass (PSG), silicon nitride, silicon oxynitride or combination thereof. The dielectric layer 230 provides a support surface for the layers to be formed thereon. The dielectric layer 230 also provides electrical insulation. In more detail, the substrate 210 in the illustrated embodiments is a “lightly-doped silicon substrate” that is relatively conductive, as discussed above. This relatively high conductivity of the substrate 210 may pose a problem when the transducer 200 is pulsed with a relatively high voltage, for example with an excitation voltage of about 60 volts to about 200 volts DC. This means that it is undesirable for a bottom electrode (discussed below in more detail) of the transducer 200 to come into direct contact with the silicon substrate 210. According to the various aspects of the present disclosure, the dielectric layer 230 helps insulate the bottom electrode of the transducer 230 from the relatively conductive surface of the silicon substrate 210.

A conductive layer 240 is then formed over the dielectric layer 230. The conductive layer 240 may be formed by a suitable deposition process such as CVD, PVD, ALD, etc. In the illustrated embodiment, the conductive layer 240 includes a metal or multiple metals material. For example, the metal or multiple metals material may include Titanium, Chromium, Gold, Aluminum, Platinum or combinations thereof. The conductive layer 240 is patterned using techniques in a photolithography process. Unwanted portions of the conductive layer 240 are removed as a part of the photolithography process. For reasons of simplicity, FIG. 2 only illustrates the conductive layer 240 after it has been patterned.

A piezoelectric film 250 is then formed over the dielectric layer 230 and the conductive layer 240. In various embodiments, the piezoelectric film 250 may include piezoelectric materials such as polyvinylidene fluoride (PVDF) or its co-polymers, polyvinylidene fluoride-trifluoroethylene (PVDF-TrFE), or polyvinylidene fluoride-tetrafluoroethlene (PVDF-TFE). Alternatively, polymers such as PVDF-CTFE and PVDF-CFE or sol-gel formed piezoelectric material may be used. In the illustrated embodiment, the piezoelectric material used in the piezoelectric film 250 contains PVDF-TrFE.

The piezoelectric film 250 is patterned to achieve a desired shape, for example the shapes shown in FIG. 2. Unwanted portions of the piezoelectric film 250 are removed in the patterning process. As a result, portions of the dielectric layer 230 and the conductive layer 240 are exposed. In the present embodiment, the piezoelectric film 250 is etched in a manner to form a chamfer to allow deposition for a top electrode to be formed. The chamfer may manifest itself as the trapezoidal sidewall shown in the cross-sectional view of FIG. 2. It is also understood that an adhesion-promoting layer (not illustrated herein) may be formed between the piezoelectric film 250 and the conductive layer 240 in some embodiments, so that the piezoelectric film 250 is more likely to stick to the conductive layer 240.

A conductive layer 270 (i.e., the top electrode) is formed over the piezoelectric film 250 using a suitable deposition process known in the art. In the illustrated embodiment, the conductive layer 270 includes a metal or multiple metals material, such as Titanium, Chromium, Gold, Aluminum, or combinations thereof. After its deposition, the conductive layer 270 is patterned using techniques in a photolithography process. Unwanted portions of the conductive layer 270 are removed as a part of the photolithography process. For reasons of simplicity, FIG. 2 only illustrates the conductive layer 270 after it has been patterned.

The conductive layers 240 and 270 and the piezoelectric layer 250 (and the adhesion-promoting layer in embodiments where it is used) may collectively be considered a transducer membrane. It is understood that pad metals may also be formed to establish electrical connections with the conductive layers 240 and 270, but these pad metals are not illustrated herein for reasons of simplicity.

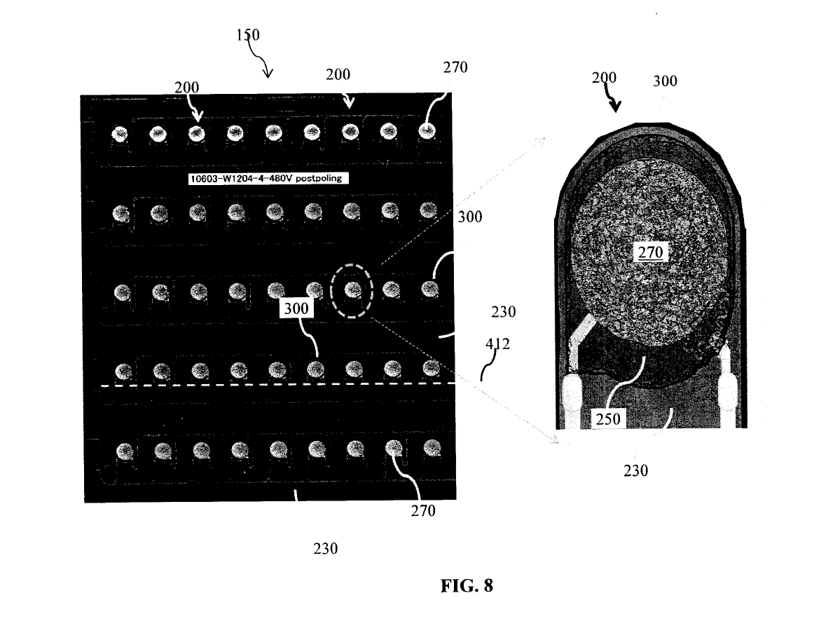

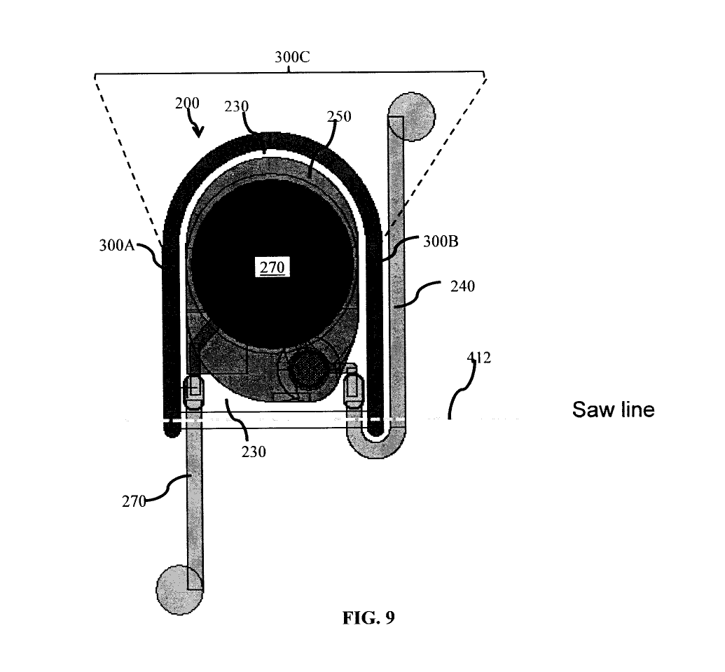

Referring now to FIG. 3, a plurality of trenches (or openings/recesses) 300 are formed in the substrate 210 from the front side 212. Each of the trenches 300 partially surrounds or encircles a respective one of the transducers. The top view of the trenches 300 are illustrated in FIGS. 8-9 and will be discussed in more detail later. In the cross-sectional view of FIG. 2, only one of such trenches 300 is shown. It is understood that the trenches 300A and 300B are actually parts of a single continuous trench that surrounds the transducer 200, even though they appear as two trenches in the cross-sectional view of FIG. 3. In the present embodiments, the trenches 300 have a trench depth 310 that is in a range from about 80 um to about 100 um. Of course, the depth 310 may have different values in alternative embodiments.

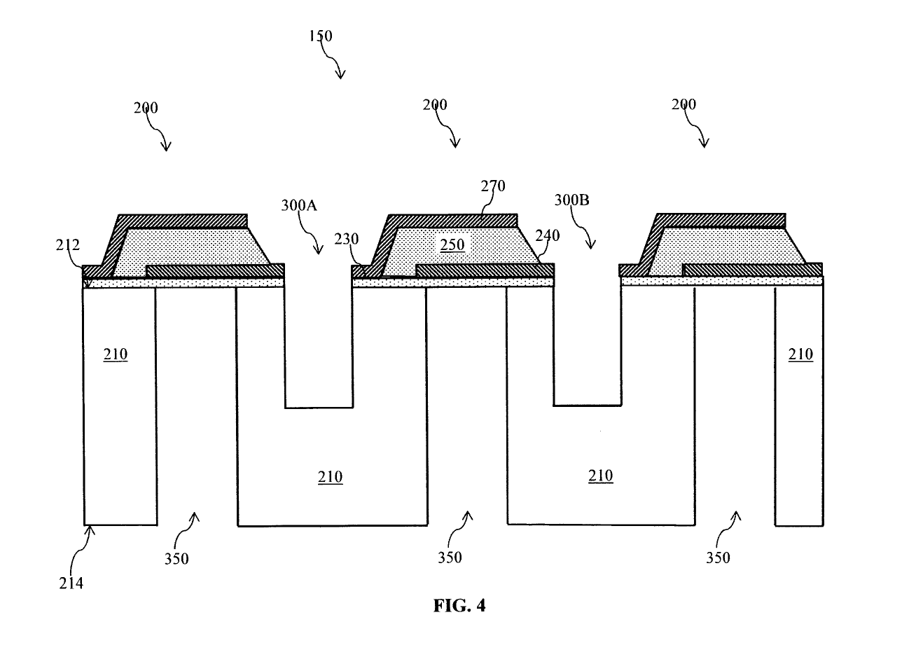

Referring now to FIG. 4, a plurality of openings 350 is formed in the substrate 210 from the back side 214. Each opening 350 is formed under a respective one of the transducers 200. The openings 350 may also be referred to as wells, voids, or recesses. The openings 350 are formed up to the dielectric layer 230 in the illustrated embodiment. In other words, a portion of the dielectric layer 230 is exposed by the openings 350. However, it is understood that in other embodiments, the openings 350 may go up through the dielectric layer 230 and stop at the conductive layer 240 (i.e., bottom electrode). In some embodiments, the openings 350 are formed by an etching process, for example a deep reactive ion etching (DRIE) process. Each opening 350 forms an aperture of the transducer 200.

It is understood that although the present embodiment involves forming the trenches 300 from the front side 212 before forming the openings 350 from the back side 214, these processes may be reversed in other embodiments. In other words, the openings 350 may be formed before the trenches 300 in other embodiments.

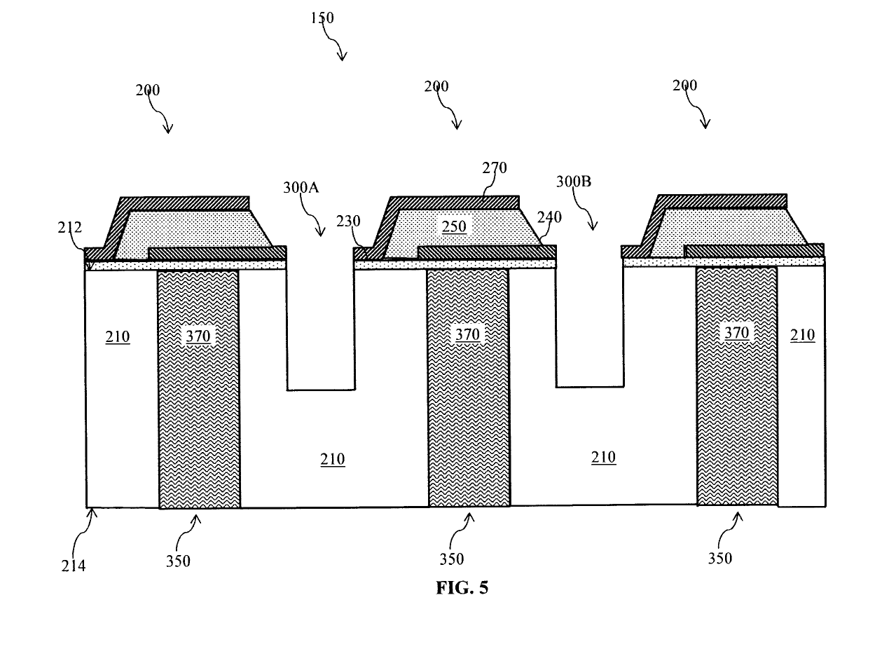

Referring now to FIG. 5, the openings 350 are filled with a backing material 370. The backing material 370 filling the opening 350 allows the membrane position to be fixed and also deadens the sound waves coming from the back of the piezoelectric film 250. In more detail, the backing material 370 physically contacts the bottom surface (or back side surface) of the dielectric layer 230 (or the back surface of the conductive layer 240 in embodiments where the dielectric layer 230 has been removed in the opening 350). Therefore, one function of the backing material 370 is that it helps lock the transducer membrane 360 into place such that its shape (for example an arcuate shape) is maintained. The backing material 370 also contains an acoustically attenuative material so that it can absorb acoustic energy (in other words, sound waves) generated by the transducer membrane 360 that travels (propagates) into the ultrasound transducer 200 (for example, from the transducer membrane 360 into the backing material 370). Such acoustic energy includes acoustic energy that is reflected from structures and interfaces of a transducer assembly, for example when the ultrasound transducer 200 is included in the transducer assembly 122 of FIG. 1.

To adequately deaden the sound waves, the backing material 370 may have a highacoustic impedance. In the present embodiment, the backing material 370 includes an epoxy material. In various other embodiments, the backing material 370 may include other materials that provide sufficient acoustical attenuation and mechanical strength for maintaining the shape of the transducer membrane 360. The backing material 370 may include a combination of materials for achieving such acoustical and mechanical properties. In some embodiments, the epoxy being used include EPO-Tek 301 or EPO-Tek 353ND. However, epoxy alone may not be sufficient as the backing material 370. In some embodiments, the epoxy is manipulated by adding filler materials such as Tungsten, Silver, Cerium Oxide or Tungsten Oxide. These materials are denser. Density multiplied by the speed of sound equals acoustic impedance. For PVDF-TrFE transducers, a relatively high acoustic impedance is desired, and most if not all epoxies have low acoustic impedance. Therefore, filler materials are added to drive up the acoustic impedance and reflect sound that comes off the back of the transducer, back toward the front, which boosts the signal.

It is understood that in some embodiments, the backing material 370 may substantially fill the entirety of the openings 350. However, in other embodiments, the backing material 370 may only partially fill the openings 350.

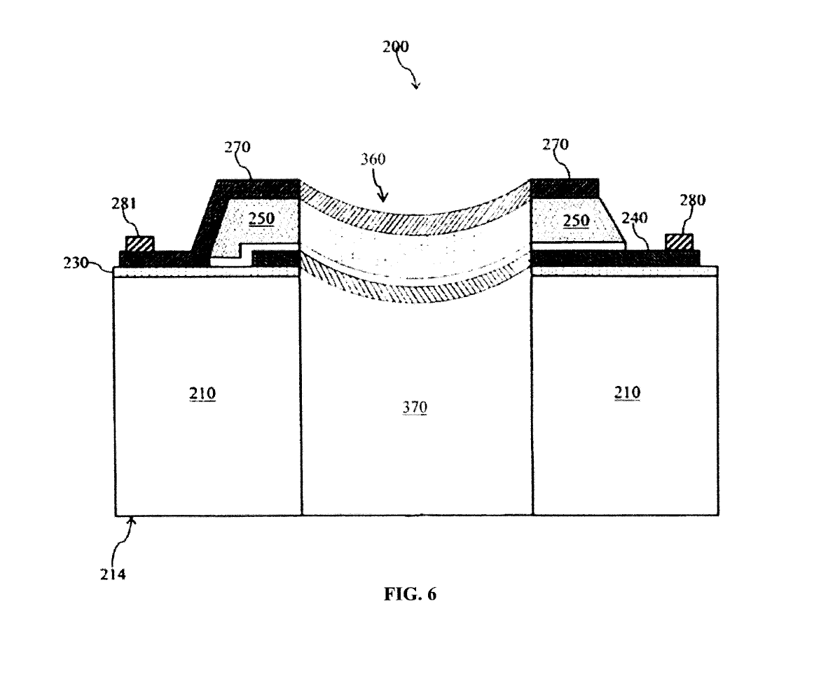

The layers disposed over the opening 350 (i.e., the transducer membrane) are also deflected to form a concave surface. Stated differently, the portion of the dielectric layer 230 exposed by the opening 350 as well as the portions of the transducer membrane disposed over the portion of the dielectric layer 230 are bent toward the back side 214. Therefore, an arcuate-shaped transducer membrane 360 is formed. For the sake of simplicity, the arcuate-shaped transducer membrane is not illustrated for all the transducers 200 of FIG. 5, but it is understood that each transducer 200 may be shaped as (or similar to) the transducer 200 shown in FIG. 6. Additional details of shaping the transducer membrane are disclosed in Provisional U.S. Patent Application 61/745,344, titled “Method and Apparatus For Shaping Transducer Membrane” to Dylan Van Hoven, filed on Dec. 21, 2012, attorney docket 44744.1094, the contents of which are hereby incorporated by reference in its entirety.

The arcuate shape of the transducer membrane 360 helps it spherically focus ultrasound signals emitted therefrom. In different embodiments, the transducer membrane 360 may exhibit other shaped configurations to achieve various other focusing characteristics. For example, in an alternative embodiment, the transducer membrane 360 may have a more arcuate shape or a more planar shape. Also, it is understood that the transducer membrane 360 may be shaped before or during the backing material 370 is applied to fill the wells 350.

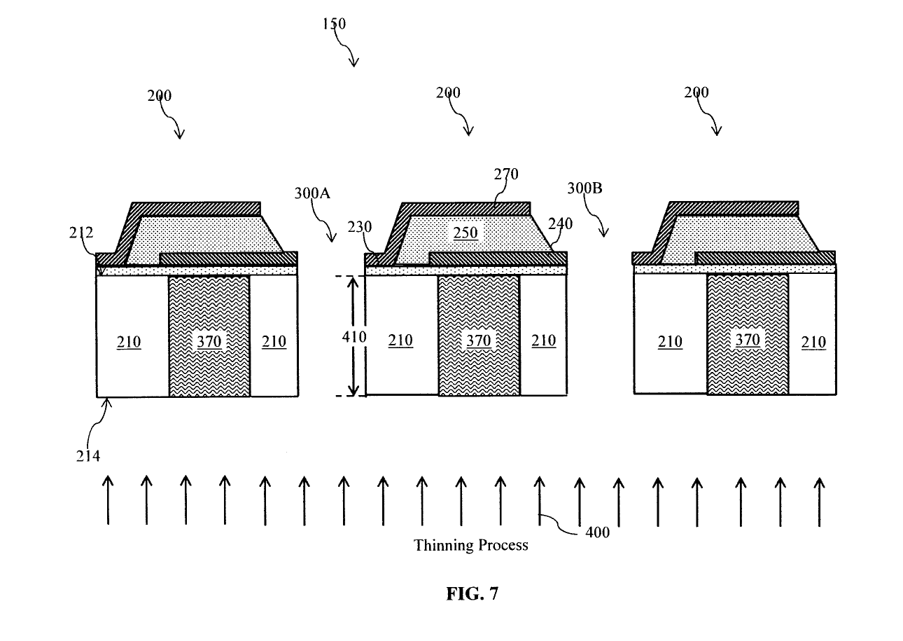

Referring now to FIG. 7, a thinning process 400 is performed from the back side 214 to reduce the thickness of the substrate 210. In some embodiments, a polishing or etching process or combinations thereof may be used to remove portions of the substrate 210 (and the backing material 370 in embodiments where applicable) from the back side 214. The thinning process 400 is performed until the substrate 210 reaches a desired thickness 410. The thickness 410 is no greater than the depth 310 of the trenches 300 (shown in FIG. 3). In some embodiments, the thickness 410 of the substrate 210 after the thinning process 400 is performed is less than about 80 um, for example about 75 um.

One reason for the thinning process 400 is to singulate the transducers 200. As can be seen from the cross-sectional view of FIG. 7, the thinning process 400 purposely thins the substrate 210 to be less than the trench depth 310. As a result, whereas the transducers 200 (including their portions of the substrate 210 underneath) were previously joined together by the portions of the substrate 210 below the trenches 310, they are not separated by the trenches 310. However, the transducers 200 are not completely separated from one another yet, because the trenches 310 do not completely surround or encircle (in 360 degrees) the transducers 200. Therefore, an additional dicing process needs to be performed to complete the singulation process. This is discussed below with reference to FIGS. 8-9, which are simplified diagrammatic top views of a portion of the wafer 150.

Referring to FIG. 8, the top view of the portion of the wafer 150 contains a plurality of transducers 200 that are formed on the substrate 210. The substrate 210 is not directly visible in FIG. 8, as most of the substrate 210 is covered up by the dielectric layer 230, the conductive layer 270, and the piezoelectric film 250. The transducers 200 are arranged into a plurality of horizontally-parallel rows. Each transducer 200 is partially surrounded or encircled by a respective one of the trenches 300.

The trench 300 is illustrated with more clarity in FIG. 9. In the present embodiments, the trench 300 is approximately U-shaped (also referred to as a tombstone-like shape). For example, the trench 300 contains two elongate segments 300A and 300B, which are shown in the cross-sectional views of FIGS. 2-7 above. In other words, the elongate segments 300A and 300B are the illustrated portions of the trench 300 disposed on opposite sides of the transducer 200 in FIGS. 2-7. It is understood that though the elongate segments 300A-300B are shown as substantially straight segments, they may be curved or have other suitable shapes in alternative embodiments.

The trench 300 also includes a substantially curved or rounded segment 300C. The curved segment 300C joins the elongate segments 300A-300B together. In the present embodiments, the curved segment 300C surrounds or encircles the transducer 200 by at least 90 degrees (where 360 degrees would be considered complete encirclement), for example between about 90 degrees and 180 degrees. The portions of the transducer 200 encircled by the segment 300C also assumes a similar (though not necessarily identical) curved or rounded top view profile.

As discussed above, the back side wafer thinning process 400 (FIG. 7) allows the transducers 200 to be substantially separated from one another by the trenches 300. However, as the top view of FIG. 9 shows, even after the thinning process is performed, the transducers 200 are still joined together by portions of the substrate 210 “below” the trenches in the top view. Therefore, to complete the singulation process, a dicing process is performed. The dicing process involves no crossing cuts on the wafer 150. Rather, a plurality of substantially parallel cuts is made on the wafer. For example, a cut along a saw line similar to the saw line 412 shown in FIGS. 8 and 9 may be made between each pair of adjacent rows of transducers 200. The saw line 412 cuts through both of the elongate segments 300A-300B of the trench 300. The dicing process allows the transducers 200 to be completely separated into individual transducer piece/dies.

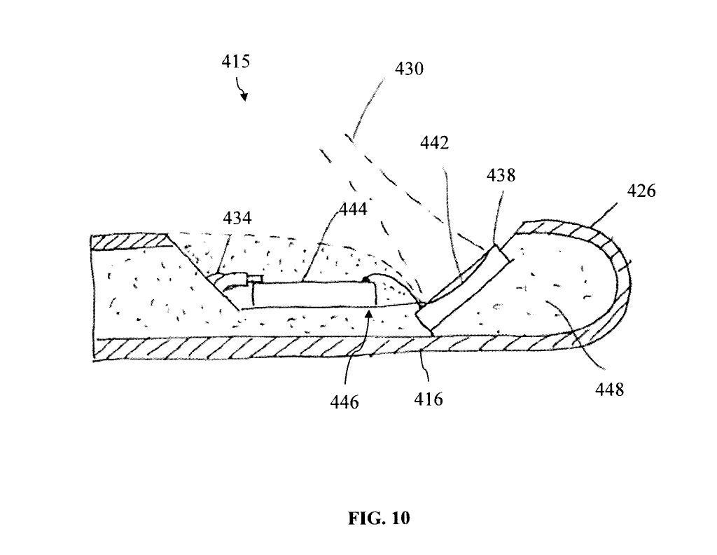

The top view profile of the trench 300 partially defines the top view of the transducer 200, specifically the edges of the substrate 210 once the transducers 200 are singulated into individual pieces. The rounded or curved profile of the substrate 210 or the transducer 200 is beneficial in ultrasound imaging applications where the transducer 200 needs to be raised at an angle. An example scenario of this is discussed below with reference to FIG. 10.

FIG. 10 illustrates a simplified diagrammatic cross-sectional view of an embodiment of an imaging core 415 that shows an embodiment of a transducer assembly. The substrate having the transducer can be positioned at an angle with respect to the substrate having associated control circuitry in the form of an Application Specific Integrated Circuit (ASIC). The substrate having the transducer is thereafter referred to as the MEMS 438, and the substrate having the ASIC is thereafter referred to as the ASIC 444.

The imaging core 415 includes a MEMS 438 having a transducer 442 (an embodiment of the transducer 200 discussed above) formed thereon and an ASIC 444 electrically coupled to the MEMS 438. The ASIC 444 and the MEMS 438 are wire-bonded together in this embodiment, mounted to the transducer housing 416, and secured in place with epoxy 448 or other bonding agent to form an ASIC/MEMS hybrid assembly 446. The leads of cable 434 are soldered or otherwise electrically coupled directly to the ASIC 444 in this embodiment.

One advantage of the wire-bonding approach is that the MEMS 438 carrying the transducer 442 can be mounted at an oblique angle with respect to the longitudinal axis of the housing 416 and imaging core 415, such that an ultrasound beam 430 emitted by the transducer 442 propagates at an oblique angle with respect to a perpendicular to the central longitudinal axis of the imaging core 415. This tilt angle helps to diminish the sheath echoes that can reverberate in the space between the transducer and the catheter sheath 412, and it also facilitates Doppler color flow imaging as disclosed in Provisional U.S. Patent Application No. 61/646,080 titled “DEVICE AND SYSTEM FOR IMAGING AND BLOOD FLOW VELOCITY MEASUREMENT” (Attorney Docket No. 44755.817/01-0145-US) and Provisional U.S. Patent Application No. 61,646,074 titled “ULTRASOUND CATHETER FOR IMAGING AND BLOOD FLOW MEASUREMENT” (Attorney Docket No. 44755.961), and Provisional U.S. Patent Application No. 61/646,062 titled “Circuit Architectures and Electrical Interfaces for Rotational Intravascular Ultrasound (IVUS) Devices” (Attorney Docket No. 44755.838), each filed on May 11, 2012 and each of which is hereby incorporated by reference in its entirety.

With conventional transducers, they are typically singulated from a wafer by crossing cuts, for example cuts that are perpendicular in a top view (i.e., both horizontal cuts and vertical cuts). The result is that the singulated piece with the transducer thereon has a substantially square or rectangular shape or profile. Such square or rectangular profile poses a problem when the transducer has to be raised at an angle, as described in the embodiment shown in FIG. 10. For example, the sharp rectangular or square edges of the transducer piece/die may prevent it from being raised at an angle, or at least not raised at a sufficient angle. In other words, the rectangular or square profiles of the transducer piece/die as a result of conventional wafer singulation processes (involving crossing cuts) may cause a spacing issue inside the transducer assembly.

In comparison, the present disclosure forms a rounded or curved trench around the transducer. The wafer singulation involves a back side wafer thinning process, as discussed above, so that the transducers are substantially separated from one another. And finally, a dicing process involving cuts in the same direction (i.e., no crossing cuts) is performed to completely separate the transducer pieces/dies from one another. The result is that the singulated transducer pieces/dies have a rounded or curved portion. This rounded or curved portion allows the transducer piece/die to be raised at an angle with no spacing issues, which makes it feasible and convenient to produce the embodiment discussed above with reference to FIG. 10.

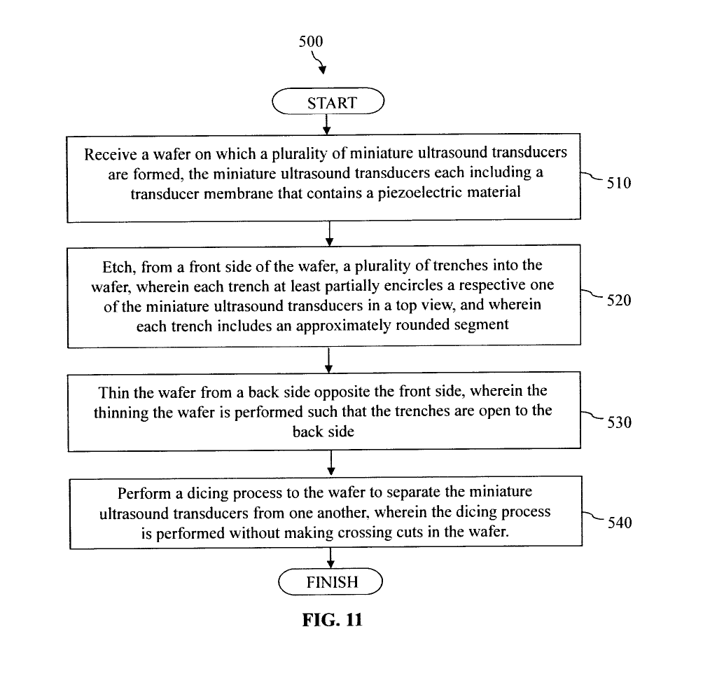

FIG. 11 is a flowchart of a method 500 for singulating a plurality of miniature ultrasound transducers from a wafer according to various aspects of the present disclosure. The method includes a step 510, in which a wafer is received. A plurality of miniature ultrasound transducers is formed on the wafer. The miniature ultrasound transducers each include a transducer membrane that contains a piezoelectric material.

The method 500 includes a step 520, in which a plurality of trenches is etched into the wafer from a front side of the wafer. Each trench at least partially encircles a respective one of the miniature ultrasound transducers in a top view. Each trench includes an approximately rounded segment;

The method 500 includes a step 530, in which thinning process is performed. The thinning process involves thinning the wafer from a back side opposite the front side. The step 530 is performed such that the trenches are open to the back side.

The method 500 includes a step 540, in which a dicing process is performed to the wafer to separate the miniature ultrasound transducers from one another. The dicing process is performed without making crossing cuts in the wafer.

In some embodiments, the rounded segment of the trench encircles at least 90 degrees of its respective miniature ultrasonic transducer.

In some embodiments, a portion of the miniature ultrasonic transducer encircled by the rounded segment of the trench has a rounded top view profile that resembles the rounded segment of the trench.

In some embodiments, the trench is approximately U-shaped and includes two elongate segments disposed on opposite sides of the transducer in a top view.

In some embodiments, the dicing process is performed so that a straight cut in the wafer is made through both of the elongate segments for each trench.

In some embodiments, the dicing process comprises making a plurality of substantially parallel cuts in the wafer.

In some embodiments, the transducer membrane has an arcuate shape in a cross-sectional view.

In some embodiments, each miniature ultrasonic transducer has a well formed in the wafer from a back side of the wafer, and wherein the transducer membrane is disposed over the well.

In some embodiments, the piezoelectric material includes polyvinylidene fluoride-trifluoroethylene (PVDF-TrFE), polyvinylidene fluoride (PVDF), or polyvinylidene fluoride-tetrafluoroethlene (PVDF-TFE).

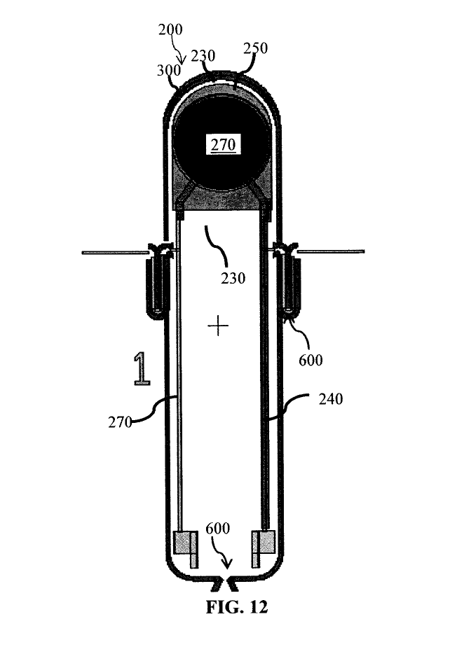

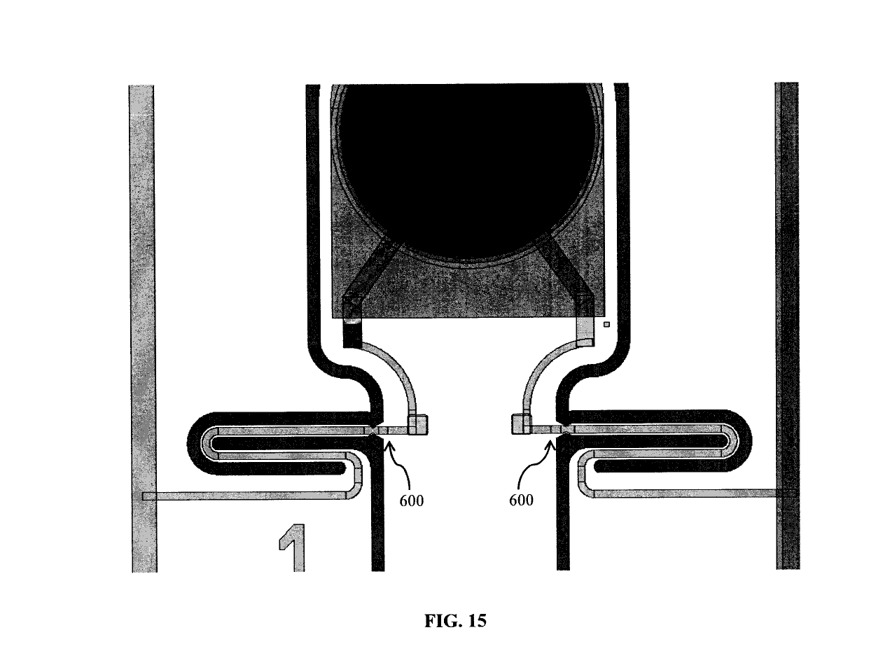

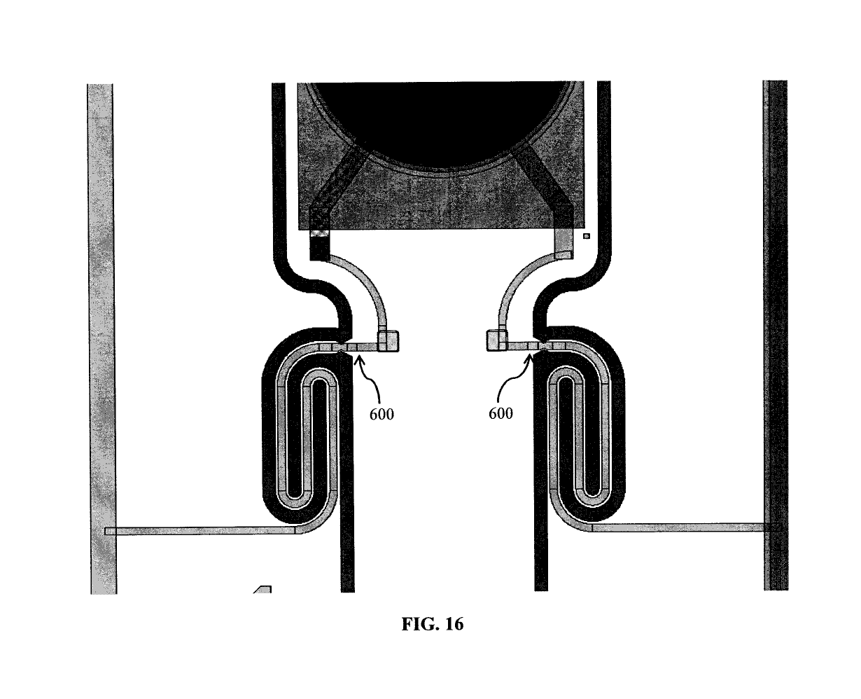

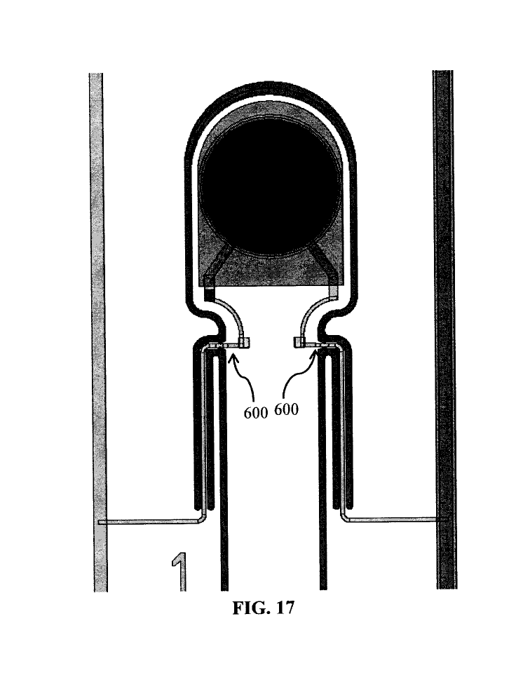

The present disclosure also discloses alternative embodiments of performing singulation. For example, whereas the embodiment discussed above with reference to FIGS. 2-9 involve forming a U-shaped (or tombstone-shaped) trench partially around each transducer, followed by back side thinning and then a dicing process, the alternative embodiments discussed below involve forming a breakable tab around each transducer (still involving the formation of trenches and backside thinning). The tab can be snapped to release each transducer. The details of these alternative embodiments are discussed below with reference to FIGS. 12-17, which are simplified diagrammatic top views of a die area around a transducer. For reasons of consistency and clarity, similar components in FIGS. 2-17 will be labeled the same.

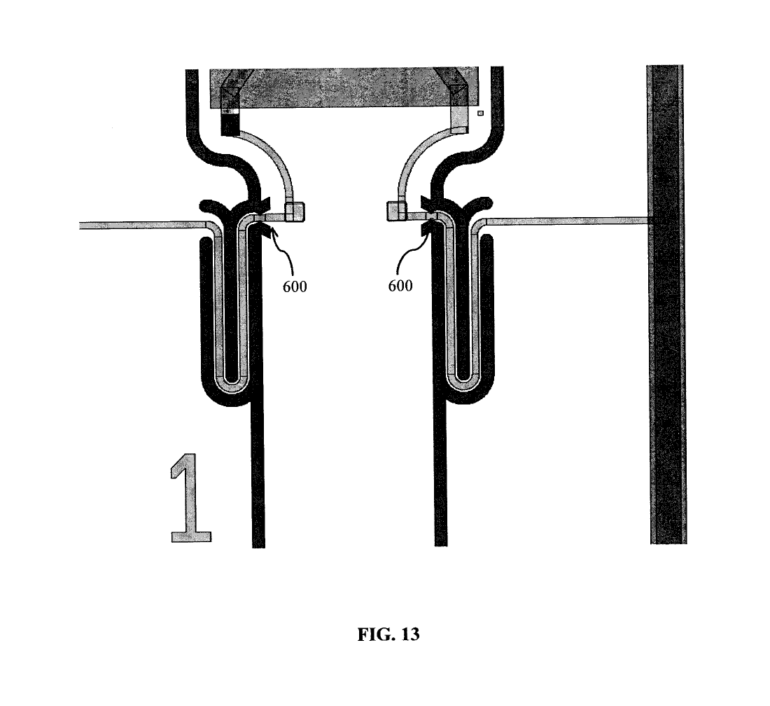

Referring to FIG. 12, the trench 300 is formed around the transducer 200. The trench substantially encircles or surrounds the transducer 200 (i.e., at or near 360 degrees) in a top view. It may be said that the trench 300 in the embodiment shown in FIG. 12 resembles a “pizza-paddle.” Of course, the U-shaped or tombstone-shaped trench shape discussed above is applicable as well. When the back side thinning process is performed, the thinning singulates the device, leaving only a small portion attached to the original wafer or substrate. The result is a “breakable” tab, which can then be snapped to release the transducer 200. Some of the example tabs are shown in FIG. 12 as tabs 600. Each tab 600 is recessed inside of the chip, for example recessed by about 25 um. In the embodiment illustrated in FIG. 13, the lateral tab 600 is within the lateral boundary of the chip.

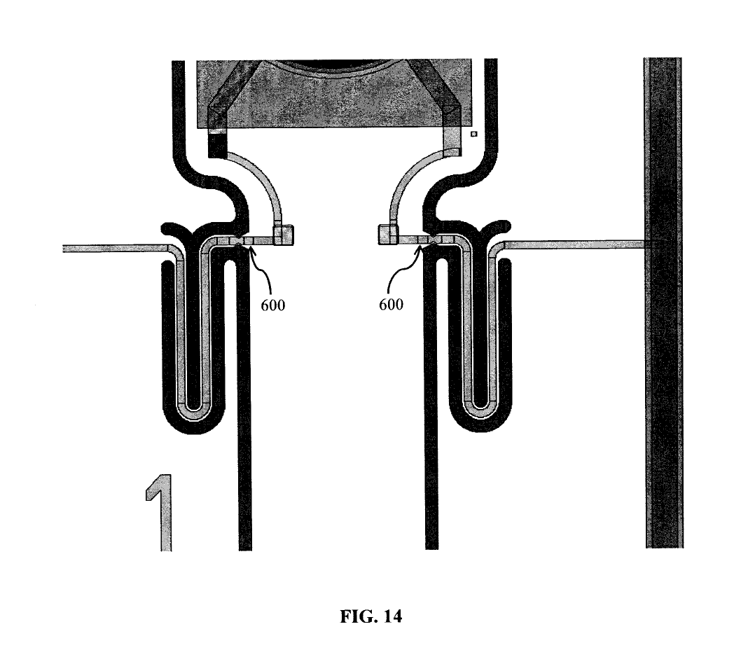

FIGS. 13-17 illustrate various locations of the tabs 600 and the layout of the trench and electrodes corresponding to different embodiments. Regardless of the particular implementation, however, it is understood that the tabs 600 are designed and configured in a manner so that they can be easily broken once the back side thinning process is complete. Once the tabs 600 are broken, the transducers 200 are separated from other transducers. It is understood that in the embodiments illustrated in FIGS. 14-17, the lateral tabs are outside the lateral boundary of the chip.

It is understood that additional fabrication steps may be performed to complete the fabrication of the transducer. However, these additional fabrication steps are not discussed herein for reasons of simplicity.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

What is claimed is:

1. A miniature ultrasound transducer, comprising:
a substrate;
a well formed the substrate; and
a transducer membrane disposed over the well, the transducer membrane containing a piezoelectric layer;
wherein at least a portion of the substrate has an approximately rounded profile in a top view.

2. The miniature ultrasound transducer of claim 1, wherein a portion of the transducer is surrounded in a top view by the portion of the substrate with the approximately rounded profile.

3. The miniature ultrasound transducer of claim 2, wherein at least 90 degrees of the transducer is surrounded in the top view by the portion of the substrate with the approximately rounded profile.

4. The miniature ultrasound transducer of claim 1, wherein the substrate is substantially U-shaped in the top view.

5. The miniature ultrasound transducer of claim 1, wherein the transducer membrane has a curved shape in a cross-sectional view.

6. The miniature ultrasound transducer of claim 1, wherein the well is at least partially filled with a backing material.

7. The miniature ultrasound transducer of claim 1, wherein the piezoelectric layer contains polyvinylidene fluoride-trifluoroethylene (PVDF-TrFE), polyvinylidene fluoride (PVDF), or polyvinylidene fluoride-tetrafluoroethlene (PVDF-TFE).

8. A wafer, comprising:
a substrate; and
a plurality of miniature ultrasonic transducers formed on the substrate;
wherein:
each miniature ultrasonic transducer includes a transducer membrane that contains a piezoelectric material;
each miniature ultrasonic transducer is at least partially surrounded in a top view by a trench formed in the substrate; and
at least a portion of the trench has an approximately curved profile in a top view.

9. The wafer of claim 8, wherein the portion of the trench that has the approximately curved profile surrounds at least 90 degrees of the miniature ultrasonic transducer.

10. The wafer of claim 8, wherein the portion of the miniature ultrasonic transducer surrounded by the portion of the trench has a curved top view profile that resembles the curved profile of the portion of the trench.

11. The wafer of claim 8, wherein the trench is approximately U-shaped.

12. The wafer of claim 8, wherein the transducer membrane has an arcuate shape in a cross-sectional view.

13. The wafer of claim 8, wherein each miniature ultrasonic transducer has a well formed in the substrate from a back side of the substrate, and wherein the transducer membrane is disposed over the well.

14. The wafer of claim 13, wherein the trench is formed from a front side of the substrate opposite the back side.

15. The wafer of claim 13, wherein the well is partially filled with a backing material.

16. The wafer of claim 8, wherein the piezoelectric material includes polyvinylidene fluoride-trifluoroethylene (PVDF-TrFE), polyvinylidene fluoride (PVDF), or polyvinylidene fluoride-tetrafluoroethlene (PVDF-TFE).

17. A method of singulating a plurality of miniature ultrasound transducers from a wafer, the method comprising:
receiving a wafer on which a plurality of miniature ultrasound transducers are formed, the miniature ultrasound transducers each including a transducer membrane that contains a piezoelectric material;
etching, from a front side of the wafer, a plurality of trenches into the wafer, wherein each trench at least partially encircles a respective one of the miniature ultrasound transducers in a top view, and wherein each trench includes an approximately rounded segment;
thinning the wafer from a back side opposite the front side, wherein the thinning the wafer is performed such that the trenches are open to the back side; and
performing a dicing process to the wafer to separate the miniature ultrasound transducers from one another, wherein the dicing process is performed without making crossing cuts in the wafer.

18. The method of claim 17, wherein the rounded segment of the trench encircles at least 90 degrees of its respective miniature ultrasonic transducer.

19. The method of claim 17, wherein a portion of the miniature ultrasonic transducer encircled by the rounded segment of the trench has a rounded top view profile that resembles the rounded segment of the trench.

20. The method of claim 17, wherein the trench is approximately U-shaped and includes two elongate segments disposed on opposite sides of the transducer in a top view.

21. The method of claim 20, wherein the dicing process is performed so that a straight cut in the wafer is made through both of the elongate segments for each trench.

22. The method of claim 17, wherein the dicing process comprises making a plurality of substantially parallel cuts in the wafer.

23. The method of claim 17, wherein the transducer membrane has an arcuate shape in a cross-sectional view.

24. The method of claim 17, wherein each miniature ultrasonic transducer has a well formed in the wafer from a back side of the wafer, and wherein the transducer membrane is disposed over the well.

25. The method of claim 17, wherein the piezoelectric material includes polyvinylidene fluoride-trifluoroethylene (PVDF-TrFE), polyvinylidene fluoride (PVDF), or polyvinylidene fluoride-tetrafluoroethlene (PVDF-TFE).
